(19) United States
(12) Patent Application Publication
(10) Pub. No.: US 2026/0028717 A1
(43) Pub. Date: Jan. 29, 2026

(54) METHOD FOR PREPARING METALLIC COBALT THIN FILM AND METHOD FOR PREPARING COBALT SILICIDE THIN FILM

(71) Applicants: INSTITUTE OF MICROELECTRONICS, CHINESE ACADEMY OF SCIENCES, Beijing (CN); BEIJING SUPERSTRING ACADEMY OF MEMORY TECHNOLOGY, Beijing (CN)

(72) Inventors: Jianfeng Gao, Beijing (CN); Shuai Yang, Beijing (CN); Weibing Liu, Beijing (CN); Junfeng Li, Beijing (CN); Jun Luo, Beijing (CN); Jinjuan Xiang, Beijing (CN); Guilei Wang, Beijing (CN)

(21) Appl. No.: 19/022,649

(22) Filed: Jan. 15, 2025

(30) Foreign Application Priority Data
Jul. 23, 2024 (CN) 202410986240.7

(51) Int. Cl. C23C 16/42; C23C 16/02; C23C 16/455

(52) U.S. Cl. CPC C23C 16/42; C23C 16/0227; C23C 16/45527

(57) ABSTRACT

A method for preparing a metallic cobalt thin film and a method for preparing a cobalt silicide thin film. A silicon-based three-dimensional substrate is preprocessed to obtain a preprocessed substrate. A cobalt buffer layer is forming in a first reaction chamber on the preprocessed substrate through first atom layer deposition (ALD), where a first gas serves as a carrier gas of the first ALD, and pulses of a first cobalt-based precursor gas and pulses of a first reaction gas are alternately introduced into the first reaction chamber. The metallic cobalt thin film is formed in a second reaction chamber on the cobalt buffer layer through second ALD, where a second gas serves as a carrier gas of the second ALD, and a second cobalt-based precursor gas and a second reaction gas are alternately introduced into the second reaction chamber in pulses.

This application claims priority to Chinese Patent Application No. 202410986240.7, titled “METHOD FOR PREPARING METALLIC COBALT THIN FILM AND METHOD FOR PREPARING COBALT SILICIDE THIN FILM,” filed on Jul. 23, 2024 with the China National Intellectual Property Administration, which is incorporated herein by reference in its entirety.

### FIELD

The present disclosure relates to the technical field of metallic thin-film preparation, and in particular to a method of preparing a metallic cobalt thin film and a method for preparing the cobalt silicide thin film.

### BACKGROUND

As semiconductor devices keep shrinking, contact resistance is regarded as a key parasitic component that determines an overall performance of a device. In advanced logic and dynamic random-access memory (DRAM) techniques, contact points are in three-dimensional deep contact holes that have a high aspect ratio. This is particularly problematic when depositing metals in deep contact holes when forming the contact points. Since physical vapor deposition (PVD) has limited conformality, a new technique for depositing a thin film is necessary.

Atomic layer deposition (ALD) is a method through which a material can be deposited layer by layer as single atomic films on a surface of a substrate. Unlike oxide or nitride film, preparing pure metal film, especially transition metal film, using the ALD method is difficult. At present, metallic cobalt films may be deposited through plasma-enhanced chemical vapor deposition (PECVD) besides the ALD. The PECVD may damage electrical performance of final devices. Additionally, the PECVD suffers from the shadowing effect when fabricating a three-dimensional structure, that is, it cannot achieve conformal deposition. Hence, the PECVD cannot meet requirements of the devices.

### SUMMARY

An objective of the present disclosure is to provide a method for preparing a metallic cobalt thin film and a method for preparing a cobalt silicide thin film. Requirements of new-type devices are well satisfied.

A method for preparing a metallic cobalt thin film is provided according to an embodiment of the present disclosure. The method comprises: preprocessing a silicon-based three-dimensional substrate to obtain a preprocessed substrate; forming, in a first reaction chamber, a cobalt buffer layer on the preprocessed substrate through first atom layer deposition (ALD), where in the first ALD, a first gas serves as a carrier gas of the first ALD, and pulses of a first cobalt-based precursor gas and pulses of a first reaction gas are alternately introduced into the first reaction chamber; and forming, in a second reaction chamber, the metallic cobalt thin film on the cobalt buffer layer through second ALD, where in the second ALD, a second gas serves as a carrier gas of the second ALD, and a second cobalt-based precursor gas and a second reaction gas are alternately introduced into the second reaction chamber in pulses.

In an embodiment, pre-processing the silicon-based three-dimensional substrate comprises performing wet processing on the silicon-based three-dimensional substrate to remove an oxide layer on the silicon-based three-dimensional substrate. In an embodiment, the wet processing utilizes a mixed solution of water and dihydrofuran (DHF), where a volume ratio of the water to the dihydrofuran in the mixed solution ranges from 100:1.5 to 100:0.5, and duration of the wet processing ranges from 30 seconds to 2 minutes.

In an embodiment, pre-processing the silicon-based three-dimensional substrate further comprises: performing degassing, pre-cleaning, and thermal processing, which are processed in the above-listed sequence, on the silicon-based three-dimensional substrate. The degassing comprises heating the silicon-based three-dimensional substrate through irradiation of a lamp or through a heating base, where a temperature of the heating ranges from 240° C. to 260° C., and duration of the heating ranges from 25 s to 35 s. The pre-cleaning utilizes first plasma that is generated from a mixed gas of NF₃ and NH₃ through a remote plasma source, where a volume ratio of the NF₃ to the NH₃ in the mixed gas ranges from 1:1.2 to 1:0.8, and duration of the pre-cleaning ranges from 15 s to 25 s. The remote plasma source utilizes radio frequency of which power ranges from 20 W to 40 W and frequency ranges from 40 KHz to 100 KHz. A temperature of the thermal processing ranges from 170° C. to 190° C., duration of the thermal processing ranges from 15 seconds to 2 minutes, and the thermal processing is configured to remove a native oxide layer on the surface of the silicon-based three-dimensional substrate.

In an embodiment, when forming the cobalt buffer layer on the preprocessed substrate, a temperature of the first reaction chamber ranges from 150° C. to 200° C., the first gas is argon, the first cobalt-based precursor gas is bis(N,N′-di-i-propylacetamidinato)cobalt(II), a temperature of the first cobalt-based precursor gas ranges from 60° C. to 70° C., duration of each pulse of the first cobalt-based precursor gas ranges from 0.5 s to 2 s, and duration of discharging the first reaction chamber after each pulse of the first cobalt-based precursor gas ranges from 0.2 s to 3 s.

In an embodiment, the first reaction gas comprises the first reaction gas comprises second plasma generated from hydrogen using another remote plasma source or is hydrogen configured to generate second plasma through another remote plasma source, duration of each pulse of the first reaction gas ranges from 0.5 s to 5 s, the another remote plasma source utilizes a radio frequency source of which power ranges from 30 W to 200 W and frequency ranges from 40 KHz to 100 KHz, duration of discharging the first reaction chamber after each pulse of the first reaction gas ranges from 0.5 s to 3 s, and a thickness of the cobalt buffer layer ranges from 0.5 nm to 1.5 nm.

In an embodiment, when forming the metallic cobalt thin film on the cobalt buffer layer, a temperature of the second reaction chamber ranges from 250° C. to 320° C., the second gas is argon, the second cobalt-based precursor gas is bis(N,N′-di-i-propylacetamidinato)cobalt(II), a temperature of the second cobalt-based precursor gas ranges from 60° C. to 70° C., duration of each pulse of the second cobalt-based precursor gas is ranges from 0.5 s to 2 s, and duration of discharging the second reaction chamber after each pulse of the second cobalt-based precursor gas ranges from 0.2 s to 3 s.

In an embodiment, the second reaction gas is hydrogen or ammonia, duration of each pulse of the second reaction gas ranges from 0.5 s to 5 s, duration of discharging the second reaction chamber after each pulse of the second reaction gas ranges from 0.5 s to 2 s, and a thickness of the metallic cobalt thin film ranges from 8 nm to 30 nm.

A method for preparing a cobalt silicide thin film is further provided according to an embodiment of the present disclosure. The method comprises: forming a metallic cobalt thin film through any foregoing embodiment; depositing a titanium nitride film on a surface of the metallic cobalt thin film; annealing the metallic cobalt thin film and the deposited titanium nitride film; and removing, after the annealing, the titanium nitride film and the remaining metallic cobalt thin film through wet cleaning.

In an embodiment, the titanium nitride film is deposited through physical vapor deposition (PVD), metal organic chemical vapor deposition (MOCVD) or thermal atomic layer deposition (ALD). A thickness of the titanium nitride film ranges from 2 nm to 10 nm. A temperature of the annealing ranges from of 800° C. to 950° C., and duration of the annealing time ranges from 25 s to 35 s.

In an embodiment, the wet cleaning comprises first wet cleaning and then second wet cleaning. The first wet cleaning utilizes a first mixed solution of NH₄OH, H₂O₂ and H₂O, where a volume ratio of NH₄OH to H₂O₂ in the mixed solution ranges from 1:1.2 to 1:0.8, and volume ratio of NH₄OH to H₂O in the mixed solution ranges from 1:6 to 1:4. A temperature of the first wet cleaning ranges from 40° C. to 60° C., and duration of the first wet cleaning ranges from 5 min to 10 min. The second wet cleaning utilizes a second mixed solution of H₃PO₄, HNO₃ and CH₃COOH, where a volume ratio of H₃PO₄ to HNO₃ in the second mixed solution ranges from 70:3 to 70:1, and a volume ratio of H₃PO₄ to in the second mixed solution ranges from 70:15 to 70:10. A temperature of the second wet cleaning ranges from 70° C. to 80° C., duration of the second wet cleaning ranges from 15 min to 25 min.

Herein the preparation method may be performed through conventional ALD equipment, and each step may be carried out in the same chamber or in different chambers. In some embodiments, the method may be performed through a multi-chamber ALD device comprising a transfer chamber and multiple processing chambers that are spaced apart around the transfer chamber. The processing chambers may be configured on requirement, and processing chamber is connected to the transfer chamber. A transfer arm in the transfer chamber is configured to move a substrate between the transfer chamber and the processing chambers, such that different processing may be performed on the substrate in the different processing chambers. The multiple chambers may comprise a degassing chamber, a pre-cleaning chamber, the first reaction chamber, the second reaction chamber, and a titanium-nitride deposition chamber, which are configured for the degassing, the pre-cleaning processing, the first ALD, the second ALD, and the deposition of titanium nitride, respectively, as mentioned above. Fabricating the metallic cobalt thin film and/or the cobalt silicide thin film through the multi-chamber ALD device can reduce costs, simplify processing, and improve efficiency of production.

The method provided herein is capable to achieve a metallic cobalt thin film in which cobalt content exceeds 90%, and resistivity reaches approximately 20 ohm-cm. The cobalt silicide thin film formed through annealing such metallic cobalt thin film can satisfy requirements of new-type devices.

### BRIEF DESCRIPTION OF THE DRAWINGS

Hereinafter drawings to be applied in embodiments of the present disclosure or in conventional technology are briefly described, in order to clarify illustration of technical solutions according to embodiments of the present disclosure or in conventional technology. Apparently, the drawings in the following descriptions are only some embodiments of the present disclosure, and other drawings may be obtained by those skilled in the art based on the provided drawings without exerting creative efforts.

FIG. 1 is a scanning electron microscopy image of a metallic cobalt thin film prepared through a method according to an embodiment of the present disclosure.

FIG. 2 is a graph of depth distribution of atoms in a metallic cobalt thin film prepared through a method according to an embodiment of the present disclosure.

FIG. 3 is a transmission electron microscopy image of a cobalt silicide thin film prepared through to a method according to an embodiment of the present disclosure.

FIG. 4 is a graph of XRD spectrum of a cobalt silicide thin film prepared through a method according to an embodiment of the present disclosure.

FIG. 5 is a scanning electron microscopy image of a metallic cobalt thin film prepared through a comparison method of the present disclosure.

FIG. 6 is a transmission electron microscopy image of a cobalt silicide thin film prepared through a comparison method of the present disclosure.

### DETAILED DESCRIPTION OF EMBODIMENTS

Hereinafter illustrative description is provided for further details of the present disclosure. Unless otherwise specified, all technical and scientific terms used herein have the same meaning which is understood by those skilled in the art to which the present disclosure pertains.

Terms used herein are only for describing specific embodiments of the present disclosure, not for limiting the embodiments. Unless clearly indicated otherwise in the context, the singular form may refer to a plurality. In addition, herein the terms “comprise” and/or “include” indicate existence of concerning feature(s), step(s), operation(s), device(s), component(s), and/or combinations of the above.

Hereinafter technical solutions in embodiments of the present disclosure are described clearly and completely in conjunction with the drawings in embodiments of the present closure. Apparently, the described embodiments are only some rather than all of the embodiments of the present disclosure. Any other embodiments obtained based on the embodiments of the present disclosure by those skilled in the art without any creative effort fall within the scope of protection of the present disclosure.

### First Embodiment

A method for preparing a metallic cobalt thin film is provided according to an embodiment. The method comprises following steps S1 to S3.

In step S1, a silicon-based three-dimensional (3D) substrate is preprocessed.

First, the silicon-based 3D substrate was subject to wet processing using a mixed solution of water and dihydrofuran (DHF). A volume ratio of water and DHF in the mixed solution was 100:1. Duration of the wet processing was 30 s. After the wet processing, an oxide layer on the silicon-based three-dimensional substrate was removed.

Then, the silicon-based 3D substrate was heated on a heating base to degas the silicon-based 3D substrate. A temperature of the heating was controlled at 250° C. and lasts for 30 s.

Afterwards, the silicon-based 3D substrate was subject to pre-cleaning using first plasma, which was generated from a mixed gas of NF₃ and NH₃ through a remote plasma source. A ratio of NF₃ and NH₃ in the mixed gas was 1:1. A temperature of the heating base was controlled to be 35° C. Duration of the pre-cleaning was 20 s. The remote plasma source utilized radio frequency, of which power was 30 W and frequency was 70 KHz.

Then, the silicon-based 3D substrate was heated to a temperature of 180° C. for 1 minute to remove a native oxide layer that was on its surface. Thereby, a preprocessed silicon-based 3D substrate was obtained.

In step S2, a cobalt buffer layer is formed.

The preprocessed silicon-based 3D substrate was transferred to a first reaction chamber that provides a vacuum environment. A temperature of the first reaction chamber was controlled at 180° C., and argon served as a first carrier gas. Pulses of bis(N,N′-di-i-propylacetamidinato)cobalt(II) having a temperature of 65° C. were introduced into the first reaction chamber. In each cycle, duration of the pulse of bis(N,N′-di-i-propylacetamidinato)cobalt(II) was Is, the first reaction chamber was discharged for 2 s after such pulse, and then a pulse of second plasma which is generated from hydrogen using a remote plasma source was introduced into the first reaction chamber, and hence the atomic layer deposition (ALD) is activated. The remote plasma source utilized radio frequency of which power was 120 W and frequency was 70 KHz. In each cycle, the duration of the pulse of the second plasma was 3 s, and the first reaction chamber was discharged for 2 s after such pulse. The above cycle was repeated for 6 cycles to form the cobalt buffer layer on the preprocessed silicon-based 3D substrate. A thickness of the cobalt buffer layer was about 1 nm.

In step S3, a metallic cobalt thin film is formed.

The preprocessed silicon-based 3D substrate having the cobalt buffer layer was transferred to a second reaction chamber providing a vacuum environment. The second reaction chamber was controlled at a temperature of 280° C. Argon served as a second carrier gas. Pulses of bis(N,N′-di-i-propylacetamidinato)cobalt(II) having a temperature of 65° C. were introduced into the second reaction chamber. In each cycle, duration of the pulse of bis(N,N′-di-i-propylacetamidinato)cobalt(II) was Is, the second reaction chamber was discharged for 2 s after such pulse, and then a pulse of hydrogen was introduced into the second reaction chamber, and hence the ALD is activated. In each cycle, duration of the pulse of the hydrogen was 3 s, and the second reaction chamber was discharged for Is after such pulse. The above cycle was repeated for 466 cycles to form the metallic cobalt thin film on the cobalt buffer layer. A thickness of the metallic cobalt thin film is about 30 nm.

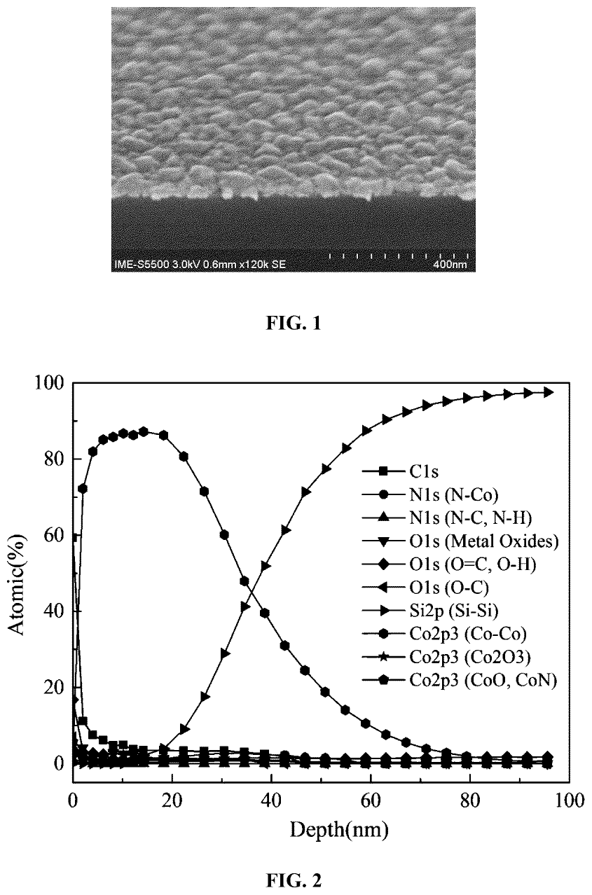

A scanning electron microscopy (SEM) image of the metallic cobalt thin film fabricated in this embodiment is as shown in FIG. 1, and a graph of depth distribution of atoms of the metallic cobalt thin film fabricated in this embodiment is as shown in FIG. 2. The results show that a surface of the metallic cobalt thin film is flat and a main content of the thin film is metallic cobalt.

Cobalt content and resistivity of the metallic cobalt thin film fabricated in this embodiment were tested. The results show that the cobalt content is 90% and the resistivity is about 18 ohm-cm.

### Second Embodiment

The second embodiment is identical to the first example except that the cycle in step S3 was repeated for 155 cycles. A thickness of the metallic cobalt thin film is about 8 nm.

### Third Embodiment

A method for preparing a cobalt silicide thin film is provided according to an embodiment. The method comprises preparing a metallic cobalt thin film and forming the cobalt silicide thin film.

First, the metallic cobalt thin films were prepared through the method in the first embodiment and the method in the second embodiment to form two groups of samples, respectively.

Then, the cobalt silicide thin films were fabricated on each sample.

In this embodiment, titanium nitride was deposited on the metallic cobalt thin film through thermal ALD. In the thermal ALD, a temperature of the base was 400° C., and TiCL₄ and NH₃ served as precursors. A source temperature of TiCl₄ was 21° C. In each cycle, a pulse of TiCl₄ lasting for 0.3 s was introduced, then TiCl₄ was discharged from pipeline(s) for 2 s, then a pulse of NH₃ lasting for 2 s was introduced, and then the NH₃ was discharged from pipeline(s) for 4 s. The above cycle was repeated for 240 cycles to form the titanium nitride layer on the metallic cobalt thin film. A thickness of the titanium nitride was 5 nm.

The preprocessed silicon-based 3D substrates deposited with the titanium nitride layers were then annealed. A temperature of the annealing was set to be 500° C., 700° C., 800° C., and 900° C. for different samples in each group. Duration of the annealing was 30 s.

The annealed preprocessed silicon-based 3D substrate was then subject to wet cleaning. The wet cleaning comprised a first wet cleaning and then a second wet cleaning. The first wet cleaning utilized a mixed solution of NH₄₀H, H₂O₂, and H₂O. A volume ratio among NH₄OH, H₂O₂, and H₂O in the mixed solution was 1:1:5. The first wet cleaning was performed at a temperature of 50° C. for 8 min. The second wet cleaning utilized a mixed solution of H₃PO₄, HNO₃, and CH₃COOH. A volume ratio among H₃PO₄, HNO₃, and CH₃COOH in the mixed solution was 70:2:12. The second wet cleaning was performed at a temperature of 75° C. for 20 min. The cobalt silicide thin film was obtained after the wet cleaning.

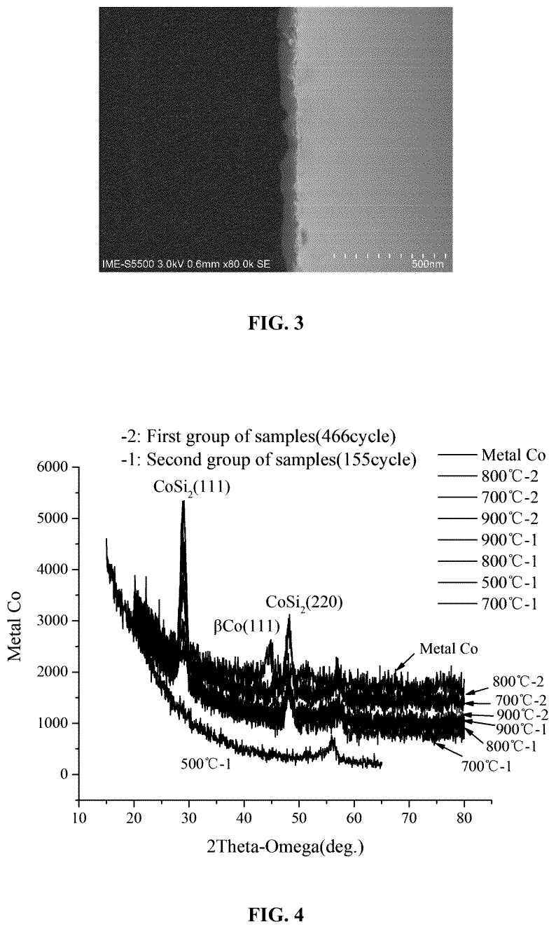

A transmission electron microscopy (TEM) image of the cobalt silicide thin film fabricated from a sample annealed at a temperature of 800° C. is as shown in FIG. 3. The results show that the cobalt metal silicide formed on the silicon-based substrate is flat.

X-ray diffraction spectra of the cobalt silicide thin films from samples annealed at temperatures of 500° C., 700° C., 800° C., and 900° C. were as shown in FIG. 4. The results show that the cobalt silicide (CoSi) may not be formed at a low temperature, e.g., 500° C., and the metallic cobalt thin film provided herein can directly form Co₂Si silicide at a temperature above 700° C.

### Fourth Embodiment

A method for preparing a cobalt silicide thin film is provided according to another embodiment. The method comprises following steps S1 to S4.

In step S1, a silicon-based 3D substrate is preprocessed.

The silicon-based 3D substrate was preprocessed in a manner identical to that in the first embodiment to obtain a preprocessed silicon-based 3D substrate.

In step S2, a cobalt buffer layer is formed.

The preprocessed silicon-based 3D substrate was transferred to a first reaction chamber that provides a vacuum environment. A temperature of the first reaction chamber was controlled at 150° C., and pulses of argon were introduced into the first reaction chamber for protection. Pulses of bis(N,N′-di-i-propylacetamidinato)cobalt(II) having a temperature of 60° C. were introduced into the first reaction chamber. In each cycle, duration of the pulse of bis(N,N′-di-i-propylacetamidinato)cobalt(II) was 0.5 s, the first reaction chamber was discharged for Is after such pulse, and then a pulse of second plasma which is generated from hydrogen using a remote plasma source was introduced into the first reaction chamber, and hence the atomic layer deposition (ALD) is activated. The remote plasma source utilized radio frequency of which power was 30 W and frequency was 40 KHz. In each cycle, the duration of the pulse of the second plasma was 0.5 s, and the first reaction chamber was discharged for is after such pulse. The above cycle was repeated for 2 cycles to form the cobalt buffer layer on the preprocessed silicon-based 3D substrate.

In step S3, a metallic cobalt thin film is formed.

The preprocessed silicon-based 3D substrate having the cobalt buffer layer was transferred to a second reaction chamber providing a vacuum environment. The second reaction chamber was controlled at a temperature of 250° C., and pulses of argon were introduced into the second reaction chamber for protection. Pulses of bis(N,N′-di-i-propylacetamidinato)cobalt(II) having a temperature of 60° C. were introduced into the second reaction chamber. In each cycle, duration of the pulse of bis(N,N′-di-i-propylacetamidinato)cobalt(II) was 0.5 s, the second reaction chamber was discharged for is after such pulse, and then a pulse of ammonia was introduced into the second reaction chamber, and hence the ALD is activated. In each cycle, duration of the pulse of the ammonia was 0.5 s, and the second reaction chamber was discharged for 0.5 s after such pulse. The above cycle was repeated for 155 cycles to form the metallic cobalt thin film on the cobalt buffer layer.

In step S4, a cobalt silicide thin film is formed.

Titanium nitride was deposited on the metallic cobalt thin film through thermal ALD, such that a titanium nitride layer having a thickness of 5 nm was formed on the metallic cobalt thin film.

The preprocessed silicon-based 3D substrate deposited with the titanium nitride layer was then annealed. A temperature of annealing was 950° C., and duration of the annealing was 25 s.

The annealed preprocessed silicon-based 3D substrate was then subject to wet cleaning in a manner identical to that in the third embodiment to obtain the cobalt silicide thin film.

### Fifth Embodiment

A method for preparing a cobalt silicide thin film is provided according to another embodiment. The method comprises following steps S1 to S4.

In step S1, a silicon-based 3D substrate is preprocessed.

The silicon-based 3D substrate was preprocessed in a manner identical to that in the first embodiment to obtain a preprocessed silicon-based 3D substrate.

In step S2, a cobalt buffer layer is formed.

The preprocessed silicon-based 3D substrate was transferred to a first reaction chamber that provides a vacuum environment. A temperature of the first reaction chamber was controlled at 200° C., and pulses of argon were introduced into the first reaction chamber for protection. Pulses of bis(N,N′-di-i-propylacetamidinato)cobalt(II) having a temperature of 70° C. were introduced into the first reaction chamber. In each cycle, duration of the pulse of bis(N,N′-di-i-propylacetamidinato)cobalt(II) was 2 s, the first reaction chamber was discharged for 3 s after such pulse, and then a pulse of second plasma which is generated from hydrogen using a remote plasma source was introduced into the first reaction chamber, and hence the atomic layer deposition (ALD) is activated. The remote plasma source utilized radio frequency of which power was 200 W and frequency was 100 KHz. In each cycle, the duration of the pulse of the second plasma was 5 s, and the first reaction chamber was discharged for 3 s after such pulse. The above cycle was repeated for 10 cycles to form the cobalt buffer layer on the preprocessed silicon-based 3D substrate.

In step S3, a metallic cobalt thin film is formed.

The preprocessed silicon-based 3D substrate having the cobalt buffer layer was transferred to a second reaction chamber providing a vacuum environment. The second reaction chamber was controlled at a temperature of 320° C., and pulses of argon were introduced into the second reaction chamber for protection. Pulses of bis(N,N′-di-i-propylacetamidinato)cobalt(II) having a temperature of 70° C. were introduced into the second reaction chamber. In each cycle, duration of the pulse of bis(N,N′-di-i-propylacetamidinato)cobalt(II) was 2 s, the second reaction chamber was discharged for 3 s after such pulse, and then a pulse of ammonia was introduced into the second reaction chamber, and hence the ALD is activated. In each cycle, duration of the pulse of the ammonia was 5 s, and the second reaction chamber was discharged for 2 s after such pulse. The above cycle was repeated for 155 cycles to form the metallic cobalt thin film on the cobalt buffer layer.

In step S4, a cobalt silicide thin film is formed.

Titanium nitride was deposited on the metallic cobalt thin film through thermal ALD, such that a titanium nitride layer having a thickness of 5 nm was formed on the metallic cobalt thin film.

The preprocessed silicon-based 3D substrate deposited with the titanium nitride layer was then annealed. A temperature of annealing was 800° C., and duration of the annealing was 35 s.

The annealed preprocessed silicon-based 3D substrate was then subject to wet cleaning in a manner identical to that in the third embodiment to obtain the cobalt silicide thin film.

### First Comparison Example

A metallic cobalt thin film having a thickness of about 30 nm was prepared on a preprocessed silicon-based 3D substrate identical to that in the first embodiment through conventional thermal ALD. Then, a titanium nitride layer having a thickness of 5 nm was formed on the metallic cobalt thin film in a manner identical to that in the third embodiment. A cobalt silicide thin film is then fabricated in a manner identical to that in the third embodiment.

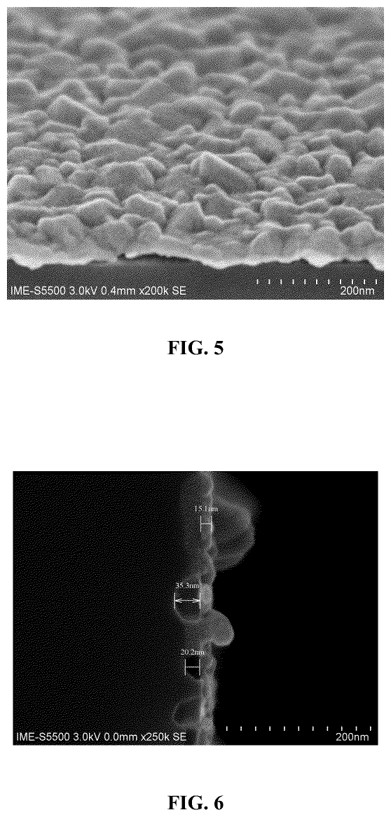

The SEM image of the metallic cobalt thin film and the TEM image of the cobalt silicide thin film in this example are as shown in FIG. 5 and FIG. 6, respectively. The results show that the surface of the metallic cobalt thin film prepared in this example is rough, and discontinuous cobalt silicide was formed after the annealing (as shown in FIG. 6).

As described above, the above embodiments are only intended to describe the technical solutions of the present disclosure, and not to limit the present disclosure. Although the present disclosure is described in detail with reference to the above embodiments, those skilled in the art should understand that, modifications can be made to the technical solutions recorded in the above embodiments, or equivalent replacements can be made to some of the technical features thereof, and the modifications and the replacements will not make the corresponding technical solutions deviate from the spirit and the scope of the technical solutions of the embodiments of the present disclosure.

1. A method for preparing a metallic cobalt thin film, comprising:
preprocessing a silicon-based three-dimensional substrate to obtain a preprocessed substrate;
forming, in a first reaction chamber, a cobalt buffer layer on the preprocessed substrate through first atom layer deposition (ALD), wherein in the first ALD, a first gas serves as a carrier gas of the first ALD, and pulses of a first cobalt-based precursor gas and pulses of a first reaction gas are alternately introduced into the first reaction chamber; and
forming, in a second reaction chamber, the metallic cobalt thin film on the cobalt buffer layer through second ALD, wherein in the second ALD, a second gas serves as a carrier gas of the second ALD, and a second cobalt-based precursor gas and a second reaction gas are alternately introduced into the second reaction chamber in pulses.

2. The method according to claim 1, wherein pre-processing the silicon-based three-dimensional substrate comprises:
performing wet processing on the silicon-based three-dimensional substrate to remove an oxide layer on the silicon-based three-dimensional substrate,
wherein the wet processing utilizes a mixed solution of water and dihydrofuran (DHF), a volume ratio of the water to the dihydrofuran in the mixed solution ranges from 100:1.5 to 100:0.5, and duration of the wet processing ranges from 30 seconds to 2 minutes.

3. The method according to claim 2, wherein pre-processing the silicon-based three-dimensional substrate further comprises:
performing degassing, pre-cleaning, and thermal processing, which are processed in the above-listed sequence, on the silicon-based three-dimensional substrate.

4. The method according to claim 3, wherein the degassing comprises heating the silicon-based three-dimensional substrate through irradiation of a lamp or through a heating base, a temperature of the heating ranges from 240° C. to 260° C., and duration of the heating ranges from 25 s to 35 s;

5. The method according to claim 3, wherein the pre-cleaning utilizes first plasma that is generated from a mixed gas of NF₃ and NH₃ through a remote plasma source, a volume ratio of the NF₃ to the NH₃ in the mixed gas ranges from 1:1.2 to 1:0.8, duration of the pre-cleaning ranges from 15 s to 25 s, and the remote plasma source utilizes radio frequency of which power ranges from 20 W to 40 W and frequency ranges from 40 KHz to 100 KHz.

6. The method according to claim 3, wherein a temperature of the thermal processing ranges from 170° C. to 190° C., duration of the thermal processing ranges from 15 seconds to 2 minutes, and the thermal processing is configured to remove a native oxide layer on the surface of the silicon-based three-dimensional substrate.

7. The method according to claim 1, wherein when forming the cobalt buffer layer on the preprocessed substrate:
a temperature of the first reaction chamber ranges from 150° C. to 200° C.,
the first gas is argon,
the first cobalt-based precursor gas is bis(N,N′-di-i-propylacetamidinato)cobalt(II),
a temperature of the first cobalt-based precursor gas ranges from 60° C. to 70° C.,
duration of each pulse of the first cobalt-based precursor gas ranges from 0.5 s to 2 s, and
duration of discharging the first reaction chamber after each pulse of the first cobalt-based precursor gas ranges from 0.2 s to 3 s.

8. The method according to claim 7, wherein:
the first reaction gas comprises second plasma generated from hydrogen using another remote plasma source or is hydrogen configured to generate second plasma through another remote plasma source,
duration of each pulse of the first reaction gas ranges from 0.5 s to 5 s,
the another remote plasma source utilizes a radio frequency source of which power ranges from 30 W to 200 W and frequency ranges from 40 KHz to 100 KHz, and
duration of discharging the first reaction chamber after each pulse of the first reaction gas ranges from 0.5 s to 3 s.

9. The method according to claim 8, wherein a thickness of the cobalt buffer layer ranges from 0.5 nm to 1.5 nm.

10. The method according to claim 1, wherein when forming the metallic cobalt thin film on the cobalt buffer layer:
a temperature of the second reaction chamber ranges from 250° C. to 320° C.,
the second gas is argon,
the second cobalt-based precursor gas is bis(N,N′-di-i-propylacetamidinato)cobalt(II),
a temperature of the second cobalt-based precursor gas ranges from 60° C. to 70° C.,
duration of each pulse of the second cobalt-based precursor gas is ranges from 0.5 s to 2 s, and
duration of discharging the second reaction chamber after each pulse of the second cobalt-based precursor gas ranges from 0.2 s to 3 s.

11. The method according to claim 10, wherein:
the second reaction gas is hydrogen or ammonia,
duration of each pulse of the second reaction gas ranges from 0.5 s to 5 s,
duration of discharging the second reaction chamber after each pulse of the second reaction gas ranges from 0.5 s to 2 s, and
a thickness of the metallic cobalt thin film ranges from 8 nm to 30 nm.

12. A method for preparing a cobalt silicide thin film, comprising:
preprocessing a silicon-based three-dimensional substrate to obtain a preprocessed substrate;
forming, in a first reaction chamber, a cobalt buffer layer on the preprocessed substrate through first atom layer deposition (ALD), wherein in the first ALD, a first gas serves as a carrier gas of the first ALD, and pulses of a first cobalt-based precursor gas and pulses of a first reaction gas are alternately introduced into the first reaction chamber;
forming, in a second reaction chamber, the metallic cobalt thin film on the cobalt buffer layer through second ALD, wherein in the second ALD, a second gas serves as a carrier gas of the second ALD, and a second cobalt-based precursor gas and a second reaction gas are alternately introduced into the second reaction chamber in pulses;
depositing a titanium nitride film on a surface of the metallic cobalt thin film;
annealing the metallic cobalt thin film and the deposited titanium nitride film; and
removing, after the annealing, the titanium nitride film and the metallic cobalt thin film, which remain, through wet cleaning.

13. The method according to claim 12, wherein:
the titanium nitride film is deposited through physical vapor deposition (PVD), metal organic chemical vapor deposition (MOCVD) or thermal ALD.

14. The method according to claim 12, wherein a thickness of the titanium nitride film ranges from 2 nm to 10 nm.

15. The method according to claim 12, wherein a temperature of the annealing ranges from of 800° C. to 950° C., and duration of the annealing time ranges from 25 s to 35 s.

16. The method according to claim 12, wherein the wet cleaning comprises first wet cleaning and then second wet cleaning, the first wet cleaning utilizes a first mixed solution of NH₄OH, H₂O₂ and H₂O, and the second wet cleaning utilizes a second mixed solution of H₃PO₄, HNO₃ and CH₃COOH.

17. The method according to claim 16, wherein:
a volume ratio of NH₄OH to H₂O₂ in the mixed solution ranges from 1:1.2 to 1:0.8, and volume ratio of NH₄OH to H₂O in the mixed solution ranges from 1:6 to 1:4; and
a temperature of the first wet cleaning ranges from 40° C. to 60° C., and duration of the first wet cleaning ranges from 5 min to 10 min.

18. The method according to claim 16, wherein:
a volume ratio of H₃PO₄ to HNO₃ in the second mixed solution ranges from 70:3 to 70:1, and a volume ratio of H₃PO₄ to in the second mixed solution ranges from 70:15 to 70:10; and
a temperature of the second wet cleaning ranges from 70° C. to 80° C., duration of the second wet cleaning ranges from 15 min to 25 min.
